(19) United States
(12) Patent Application Publication
(10) Pub. No.: US 2012/0306496 A1
(43) Pub. Date: Dec. 6, 2012

(54) HIGH-FREQUENCY ANTENNA

(76) Inventor: Stefan Popescu, Erlangen (DE)

(21) Appl. No.: 13/482,817

(22) Filed: May 29, 2012

(30) Foreign Application Priority Data
May 30, 2011 (DE) 10 2011 076 717.7

(51) Int. Cl. H01Q 1/52; B05D 1/02; B29C 45/14; G01R 33/34; B05D 5/12; B82Y 30/00; B82Y 99/00

(52) U.S. Cl. 324/322; 343/841; 427/58; 427/122; 264/104; 977/742; 977/734

(57) ABSTRACT

A high-frequency antenna unit for a magnetic resonance apparatus includes a high-frequency antenna and a shield unit. The shield unit, the high-frequency antenna, or a combination thereof is formed at least partially from a composite material. The composite material includes at least one electrically conducting material and at least one electrically non-conducting material.

This application claims the benefit of DE 10 2011 076 717.7, filed on May 30, 2011.

### BACKGROUND

The present embodiments relate to a high-frequency antenna unit for a magnetic resonance apparatus.

During a magnetic resonance measurement, pulsed electric currents flow through gradient coils of a magnetic resonance apparatus to generate changing gradient magnetic fields. These pulsed currents or changing currents interact with a constant magnetic field of the magnetic resonance apparatus within a holding region that accommodates a patient, thereby generating unwanted vibrations and noise.

The changing gradient magnetic fields generated by the gradient coils induce eddy currents within high-frequency conductors of a high-frequency antenna of the magnetic resonance apparatus and/or within a high-frequency shield of the magnetic resonance apparatus. These induced eddy currents interact with the static magnetic field and produce unwanted vibrations within the high-frequency antenna, the high-frequency conductors, and the high-frequency shield. The unwanted vibrations generate additional noise. These induced eddy currents may also generate heat within the high-frequency antenna and/or the high-frequency shield. Such heat generated in the high-frequency antenna and/or the high-frequency shield may produce an unwanted temperature rise within the holding region and/or the patient. This may have a disadvantageous effect on patient comfort and/or reduce the effectiveness of a magnetic resonance measurement as a result of, for example, an increase in thermal noise and/or performance loss of the high-frequency antenna.

### SUMMARY AND DESCRIPTION

The present embodiments may obviate one or more of the drawbacks or limitations in the related art. For example, a high-frequency antenna unit for magnetic resonance devices, where the induction of eddy currents is reduced and/or prevented, is provided.

The present embodiments are based on a high-frequency antenna unit for a magnetic resonance apparatus, for example, having a high-frequency antenna and a shield unit.

The shield unit and/or the high-frequency antenna is formed at least partially from a composite material. The composite material includes at least one electrically conducting material and one electrically non-conducting material. This allows an interaction of changing gradient fields and/or changing gradient pulses with the high-frequency antenna and/or the shield unit to be prevented, thereby at least reducing and/or preventing the induction of unwanted eddy currents within the high-frequency antenna and/or the shield unit. As a result of the reduction of eddy currents within the high-frequency antenna and/or the shield unit, acoustic noise and/or thermal heat generation and/or the formation of artifacts during imaging may at least be reduced and/or prevented.

A shield unit refers, for example, to a unit that is configured to shield high-frequency signals to the outside (e.g., from the gradient unit) and/or to shield the high-frequency antenna from external interference signals. The shield unit may be configured so that the high-frequency signals from the high-frequency antenna are reflected at the shield unit. The shield unit is disposed along a radial direction between the high-frequency antenna and the gradient unit. The shield unit and/or the high-frequency antenna may be configured so that an induction of eddy currents generated by an interaction with the gradient fields and/or the gradient pulses with the high-frequency antenna and/or the shield unit may be suppressed due to the electrical properties (e.g., an electrical conductivity) of the composite material within the high-frequency unit and/or the shield unit. A composite material also refers, for example, to a material including two or more interconnected materials. The material properties of the composite material are configurable to be different from the material properties of the individual materials of the composite material. Material properties and/or a geometry (e.g., a particle size) of the individual components and/or materials are important for the material properties of the composite material. For example, in the case of fiber-based composite materials, fibers and/or particles may be embedded in a further component of the composite material (e.g., a matrix of the composite material). The electrically non-conducting material may include an insulator that may at least partially include a ceramic, an epoxy resin, a glass, a mica, an anodized copper, metallic oxides, a natural rubber, a synthetic rubber, a silicone, or a combination thereof.

The electrically conducting material has an electrical conductivity with a value of, for example, at least 30·10⁶ Ω⁻¹m⁻¹, allowing advantageous conduction of the composite material to be achieved at high frequencies (e.g., in a frequency range of high-frequency signals from the high-frequency antenna). The electrically conducting material has a value for electrical conductivity of at least 30·10⁶ Ω⁻¹m⁻¹ at a temperature of 20° C. and with direct current. If the high-frequency antenna unit is used in a magnetic resonance apparatus, the electrically conducting material may have an electrical conductivity with a value of at least 58.0·10⁶ Ω⁻¹m⁻¹ at a temperature of 20° C. and in direct current conditions. The frequency range of high-frequency signals from the high-frequency antenna is, for example, around 63 MHz in a magnetic resonance device with a magnetic field strength of approximately 1.5 T of a main magnetic field and around 123 MHz in a magnetic resonance device with a magnetic field strength of approximately 3.0 T of a main magnetic field.

The electrically conducting material includes electrically conducting material elements that are disposed at least partially isolated from one another within the composite material, thereby advantageously allowing capacitive isolation between the individual, electrically conducting material elements within the composite material. The capacitive isolation of the individual, electrically conducting material elements brings about a frequency-dependent electrical conductivity of the composite material, so that an electrical conduction of frequency signals in a frequency range in the megahertz range and electrical non-conduction and/or isolation of frequency signals in a frequency range in the kilohertz range may be achieved. The electrically conducting material elements, which are disposed at least partially isolated from one another, may form a three-dimensional (e.g., irregular) framework and/or a three-dimensional (e.g., irregular) structure that is at least partially interrupted and is embedded within the matrix including the electrically non-conducting material. The individual, electrically conducting material elements of the electrically conducting material are isolated by the electrically non-conducting material within the composite material.

The isolated, electrically conducting material elements may be formed, for example, by individual particles. The electrically conducting material includes electrically conducting material elements that are formed at least partially by fibers and/or threads. This allows a network structure of relevance for a shield function to be achieved within the composite material. The fibers and/or threads may have a length of at least approximately 1 μm and a maximum length of approximately 2000 μm. In one embodiment, the maximum length is approximately 200 μm). A cross section of the fibers and/or threads may have a maximum value of approximately 10 μm, approximately 1.0 μm, or approximately 0.5 μm.

The electrically conducting material includes electrically conducting material elements that are formed at least partially by carbon nanotubes and/or a graphene material, allowing a composite material with electrically conducting material elements that demonstrate very small ohmic losses at high frequencies (e.g., at frequencies in the megahertz range) to be provided for the shield unit and/or the high-frequency antenna. Carbon nanotubes may be an electrically conducting material that is formed at least partially from microscopically small tube-like structures (e.g., from molecular nanotubes made of carbon (carbon nanotubes=CNT)).

In a further embodiment, the high-frequency antenna has a high-frequency antenna detuning unit having at least one conductor element that is disposed within an antenna segment of the high-frequency antenna. A high-frequency antenna detuning unit may be a unit, by which a detuning frequency range of the high-frequency antenna may be detuned in a passive and/or non-active operating mode with respect to a frequency range in an active operating mode. The detuning frequency range, for example, is configured differently from the frequency range in the active operating mode. The frequency range may be formed by a transmit frequency range and/or receive frequency range of the high-frequency antenna. The high-frequency antenna may, for example, be configured as a transmitter antenna and/or as a receiver antenna. The high-frequency antenna may include a number of antenna segments. The embodiment allows a circuit of a non-linear electrical module (e.g., a PIN diode) to be achieved to detune the high-frequency antenna, in that the conductor element may be used to overlay a detuning current on the high-frequency signal. A detuning current circuit with a conductor element is provided for each of the non-linear, electrical modules and/or a group of non-linear, electrical modules. The conductor element is disposed within the composite material.

A simple and effective implementation of the detuning of the high-frequency antenna may be achieved if the at least one conductor element at least partially includes a copper wire. The configuration of the at least one conductor element as a copper wire allows a good conductor that is suitable for detuning the high-frequency antenna to be provided with a detuning voltage. The copper wire supplies high-frequency antennas, which are formed at least partially by a composite material with a high resistance to detuning. The detuning of the high-frequency antenna takes place by feeding in a direct current. The composite material has a high resistance to the direct current. This high resistance may be bridged using the copper wire. The copper wire may have, for example, a cross section of at least 0.5 mm², allowing overheating of the copper wire to be prevented (e.g., when a current strength of at least several 100 mA is applied to the copper wire). The small cross section also allows the induction of eddy currents within the copper wire to be suppressed.

Alternatively or additionally to a configuration of the at least one conductor element as a copper wire, the at least one conductor element may also be disposed at least partially in the form of a thin conductor layer within the antenna segment. The cross sectional area of the thin conductor layer may be at least 0.5 mm², so that overheating of and/or unwanted damage to the thin conductor layer may be prevented (e.g., when a current strength of at least several 100 mA is applied to the thin conductor layer). The small cross section of the thin conductor layer also provides that an induction of eddy currents within the conductor layer may be suppressed. The thin conductor layer may be formed at least partially by a powdered metal, metal flakes, a silver material, a material containing graphite, an indium tin oxide, a fluorine-doped tin oxide, a doped zinc oxide, an organic conductor layer made of carbon nanotubes, a graphene material, or a combination thereof. The thin conductor layer may, for example, be disposed embedded within the composite material.

The present embodiments are also based on a magnetic resonance apparatus having a magnet unit and an evaluation unit. The magnet unit includes a high-frequency antenna unit, a main magnet and a gradient unit,

The present embodiments are also based on a method for producing a high-frequency antenna unit. A shield unit and/or a high-frequency antenna made of a composite material that includes at least one electrically conducting material and an electrically non-conducting material, is produced.

The composite material is sprayed onto a carrier unit. The carrier unit may include a carrier material that is formed by an electrically insulating material to prevent any unwanted impairment of the shield unit and/or the high-frequency antenna. The carrier unit may be formed, for example, by an inner face of the cylindrical gradient coil, which is cast in epoxy resin. The present embodiments allow economical and fast production of the shield unit and/or the high-frequency antenna to be achieved.

The composite material is sprayed onto the carrier unit in a liquid aggregate state and/or dissolved in a solvent. A thin layer of the composite material may be sprayed onto the carrier unit with a regular layer thickness. For example, the composite material may be applied to the carrier unit in the form of a composite material dye using a dye spraying process. The layer thickness of the composite material may be a function of a material of the composite material. For example, a minimum layer thickness of the composite material is configured so that the minimum layer thickness is approximately 1-2 penetration depths of electromagnetic waves. After one penetration depth into the composite material, an amplitude of the electromagnetic wave is 1/e of the amplitude of the electromagnetic wave striking the shield unit.

A reduction of unwanted eddy currents within the high-frequency antenna may be achieved if the composite material is sprayed onto the carrier unit with a maximum proportion of the electrically conducting material of 40% volume (e.g., maximum 30% volume to 40% volume).

The composite material is sprayed with an electrically conducting material including a graphene material and/or carbon nanotubes, thereby allowing the provision of a composite material containing an electrically conducting material demonstrating very small ohmic losses at high frequencies (e.g., at frequencies in the megahertz range) for the shield unit and/or high-frequency antenna. A minimum layer thickness of the layer of the composite material containing an electrically conducting material including a graphene material and/or carbon nanotubes may be at least 2 μm.

In one embodiment, at least one conductor element of the high-frequency antenna detuning unit is positioned on the carrier unit, and the composite material is sprayed onto the carrier unit. The high-frequency antenna unit (e.g., the high-frequency antenna) may be produced in a simple manner together with a high-frequency antenna detuning unit.

In one embodiment, a method for producing a high-frequency antenna unit includes producing a shield unit and/or a high-frequency antenna from a composite material that includes at least one electrically conducting material and at least one electrically non-conducting material.

The shield unit and/or the high-frequency antenna is produced from the composite material using an injection molding procedure, thereby allowing simple and economical production of the shield unit and/or the high-frequency antenna to be achieved.

### BRIEF DESCRIPTION OF THE DRAWINGS

FIG. 1 shows a schematic diagram of one embodiment of a magnetic resonance apparatus;

FIG. 2 shows a magnet unit having one embodiment of a high-frequency antenna unit;

FIG. 3 shows one embodiment of a high-frequency antenna unit with a high-frequency antenna detuning unit; and

FIG. 4 shows a flowchart of one embodiment of a production method.

### DETAILED DESCRIPTION OF THE DRAWINGS

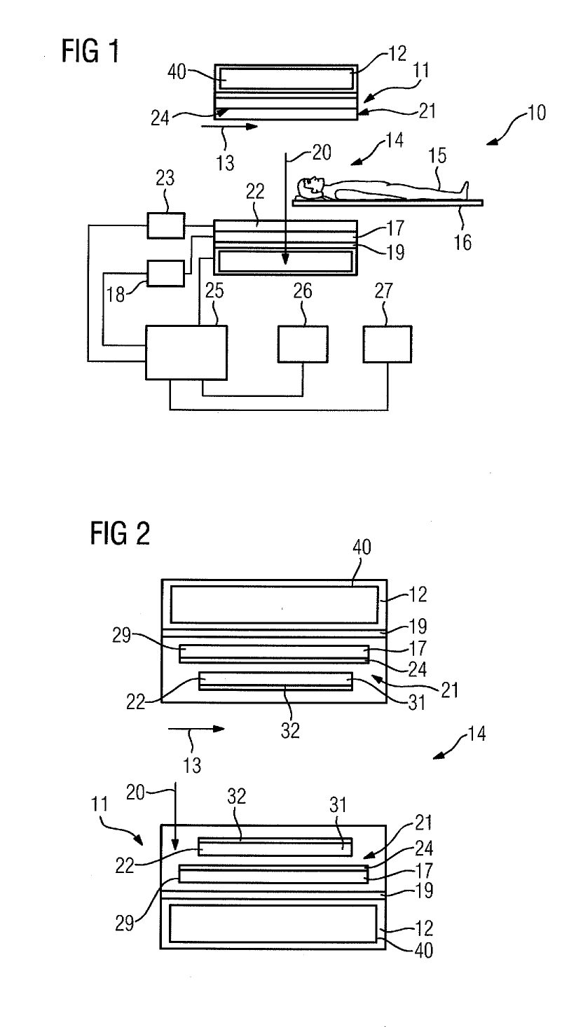

FIG. 1 shows one embodiment of a magnetic resonance apparatus 10. The magnetic resonance apparatus 10 includes a magnet unit 11 with a main magnet 12 for generating a powerful and, for example, constant main magnetic field 13 (FIGS. 1 and 2). The main magnet 12 of the magnet unit 11 includes superconducting magnet coils 40. The magnetic resonance apparatus 10 also includes a cylindrical holding region 14 that accommodates a patient 15, the holding region 14 being enclosed in a peripheral direction by the magnet unit 11. The patient 15 may be moved by a patient couch 16 of the magnetic resonance apparatus 10 into the holding region. The patient couch 16 is disposed in a movable manner within the magnetic resonance apparatus 10.

The magnet unit 11 also has a gradient coil 17 for generating magnetic field gradients. The gradient coil 17 is used for spatial encoding during imaging. The gradient coil 17 is controlled by a gradient control unit 18. The magnet unit 11 also includes a shim unit 19 that is disposed along a radial direction 20 between the gradient coil 17 and the main magnet 12. The shim unit 19 is used to compensate for non-homogeneities of the main magnetic field 13, so that the most homogeneous main magnetic field 13 possible is available for magnetic resonance examinations (FIGS. 1 and 2).

The magnet unit 11 further includes a high-frequency antenna unit 21 that includes a high-frequency antenna 22, and a high-frequency antenna control unit 23. The high-frequency antenna unit 21 excites a polarization that is established in the main magnetic field 13 generated by the main magnet 12. The high-frequency antenna 22 is controlled by the high-frequency antenna control unit 23 and emits high-frequency magnetic resonance sequences into an examination chamber. The examination chamber is essentially formed by the holding region 14. The high-frequency magnetic resonance sequences deflect magnetization from an equilibrium position. Magnetic resonance signals are also received by the high-frequency antenna 22. The high-frequency antenna unit 21 also includes a shield unit 24 (FIG. 2).

To control the main magnet 12, the gradient control unit 18 and the high-frequency antenna control unit 23, the magnetic resonance apparatus 10 has a control unit 25 formed by a computation unit. The control unit 25 controls the magnetic resonance apparatus 10 centrally (e.g., the performance of a predefined imaging gradient echo sequence). The control unit 25 also includes an evaluation unit for evaluating image data. Control information such as, for example, imaging parameters, and reconstructed magnetic resonance images may be displayed to an operator of the magnetic resonance apparatus 10 on a display unit 26 (e.g., on at least one monitor) of the magnetic resonance apparatus 10. The magnetic resonance apparatus 10 also has an input unit 27, by which an operator may input information and/or parameters during a measurement process. The input unit 27 may include, for example, a keyboard and/or a computer mouse and/or further input elements.

The illustrated magnetic resonance apparatus 10 may include further components that magnetic resonance apparatuses 10 normally have. The general mode of operation of a magnetic resonance apparatus 10 is also known to the person skilled in the art, so a detailed description of the general components is not provided.

The shield unit 24 is disposed along the radial direction 20 between the high-frequency antenna 22 and the gradient coil 17. The shield unit 24 is also configured to be cylindrical and is disposed on an inner face of a cylindrical carrier unit 29 of the gradient coil 17. The cylindrical carrier unit 29 supports the gradient coil 17, with the cylindrical carrier unit 29 being formed from an electrically insulating material (e.g., an epoxy resin). The gradient coil 17 is, for example, cast in the cylindrical carrier unit 29, with the carrier unit being formed, for example, by an epoxy resin or a glass fiber-reinforced plastic (GFRP). In an alternative embodiment of the high-frequency antenna unit 21, the shield unit 24 may be disposed within the high-frequency antenna unit 21 independently of the gradient coil 17 and/or in further regions, where an advantageous shielding may be achieved.

The high-frequency antenna 22 has a high-frequency antenna line 31, which is configured to feed and/or supply the high-frequency antenna 22 with high-frequency signals. The high-frequency antenna line 31 is disposed on a cylindrical carrier unit 32, which is formed by a high-frequency antenna holder of the high-frequency antenna 22. The cylindrical carrier unit 32 of the high-frequency antenna 22 is formed from an electrically insulating and/or non-conducting material such as, for example, an epoxy resin and/or a glass fiber-reinforced plastic.

For effective signal conduction of high-frequency signals and effective suppression of induced eddy currents in a frequency range of up to several kilohertz, the shield unit 24 and the high-frequency antenna 22 are formed at least partially from a composite material. The composite material includes a first, electrically conducting material and a second, electrically non-conducting material. In an alternative embodiment, the composite material may also include further electrically conducting materials and/or electrically non-conducting materials.

The electrically non-conducting material is formed, for example, by a ceramic. Also, at high frequencies (e.g., at frequencies of high-frequency signals from the high-frequency antenna), the electrically non-conducting material demonstrates small dielectric losses tan(δ). The loss angle δ defines a ratio of active power to reactive power of the electrically non-conducting material with an arc tangent. Alternatively or additionally, the electrically non-conducting material may also be formed by an epoxy resin, a glass, a mica, an anodized copper, a metallic oxide, a natural rubber material, a synthetic rubber material, a silicone, any other electrically non-conducting materials, or combinations thereof. The electrically non-conducting material forms an electrically non-conducting matrix within the composite material. Electrically conducting material elements of the electrically conducting material are embedded and/or disposed within the electrically non-conducting matrix.

In one embodiment, the electrically conducting material has an electrical conductivity that has a value of at least 58.0·10⁶ Ω⁻¹m⁻¹ at a temperature of approx. 20° C. and with a direct current, to allow conduction of signals at frequencies in the megahertz range within the high-frequency antenna 22 and the shield unit 24 (e.g., the composite material). In an alternative application of the high-frequency antenna unit 21 for a magnetic resonance apparatus 10, the electrically conducting material may also have an electrical conductivity of at least 30·10⁶ Ω⁻¹m⁻¹ at 20° C. and with direct current.

In one embodiment, the electrically conducting material is also formed by individual electrically conducting material elements that are disposed at least partially isolated from one another within the electrically non-conducting matrix formed from the electrically non-conducting material. The electrically conducting material elements of the electrically conducting material may be formed by threads and/or fibers. The electrically conducting material elements of the electrically conducting material may be formed by carbon nanotubes (CNT) and/or a graphene material, so that conductivity with small ohmic losses for the electrically conducting material and/or conduction of signals with frequencies in the megahertz range is/are present within the high-frequency antenna 22 and the shield unit 24. In one embodiment, the fibers and/or threads made from the carbon nanotubes and/or from the graphene material have a maximum cross section of approximately 10 μm. In another embodiment, the maximum cross section is approximately 1.0 μm. In yet another embodiment, the maximum cross section is approximately 0.5 μm. The length of the fibers and/or threads made from the carbon nanotubes and/or the graphene material is between 1 and approximately 2000 μm (e.g., between 1 μm and approximately 200 μm).

The electrically conducting material elements of the electrically conducting material are disposed within the composite material or the matrix formed from the electrically non-conducting material to form a three-dimensional, irregular framework and/or a three-dimensional, irregular structure, so that the electrically conducting material elements form a network-type framework and/or a network-type structure within the electrically non-conducting matrix. The three-dimensional, irregular framework and/or the three-dimensional, irregular structure is/are interrupted, so that the individual, electrically conducting material elements are disposed at least partially spatially isolated from one another within the three-dimensional, irregular framework and/or the three-dimensional, irregular structure. The arrangement of the individual, electrically conducting material elements is irregular, however, so that the distance between the individual, electrically conducting material elements is also irregular. A space between the individual electrically conducting material elements is filled by the electrically non-conducting material.

The spatial isolation between the individual, electrically conducting material elements brings about capacitive isolation between the individual, electrically conducting material elements. The distance between the individual, electrically conducting material elements is, for example, selected so that frequency signal conduction takes place for frequency signals in the megahertz range, and frequency signal conduction within the composite material is prevented for frequency signals in the hertz to kilohertz range. The distance between the individual, electrically conducting material elements, for example, is a function of the length, cross sectional area, and/or the concentration of the electrically conducting material elements within the composite material. The concentration of electrically conducting material elements within the composite material is maximum 40% volume (e.g., maximum 30% volume to 40% volume).

For frequency signals in a low frequency range (e.g., for frequency signals in the hertz to kilohertz range), the composite material demonstrates a low electrical conductivity due to the interrupted three-dimensional, irregular framework and/or the interrupted three-dimensional, irregular structure. Accordingly, electrical eddy currents induced by the gradient fields and/or gradient pulses (e.g., having a frequency in the kilohertz range) are reduced and/or prevented. In this frequency range, the electrical conductivity of the composite material may have a conductivity value of an insulator. In contrast, for frequency signals from the high-frequency antenna (e.g., for frequency signals in the megahertz range), the composite material has a high conductivity, so that conduction of high-frequency signals from the high-frequency antenna 22 and the shield unit 24 in a frequency range of several megahertz thus takes place. A composition of the composite material is configured so that a specific resistance is minimal in the megahertz range but assumes a maximum value in the hertz and kilohertz range.

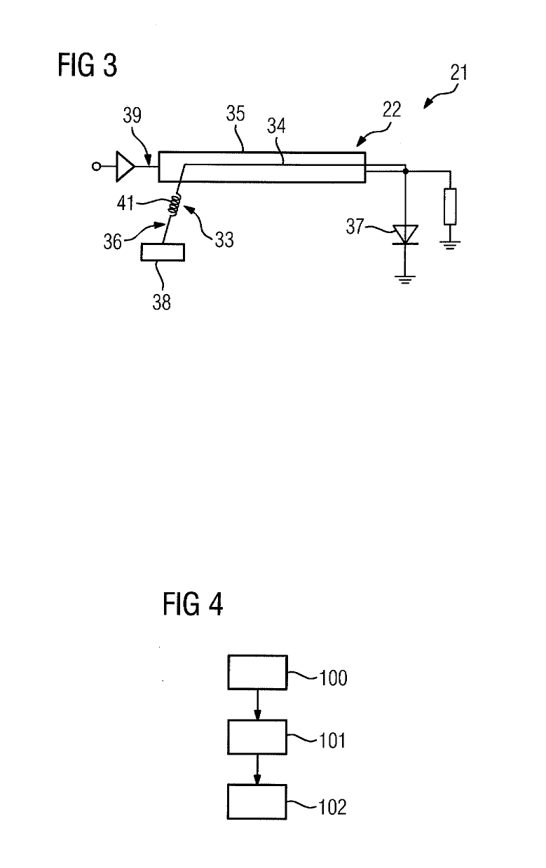

The high-frequency antenna unit 21 further includes a high-frequency antenna detuning unit 33 that is configured to detune the high-frequency antenna 22 in a passive operating mode and/or when the high-frequency antenna 22 is not operating (FIG. 3). The high-frequency antenna detuning unit 33 has a number of conductor elements 34, each disposed in an antenna segment 35. An antenna segment 35 with a conductor element 34 is shown by way of example in FIG. 3. The conductor elements 34 are formed from a thin copper wire. A cross sectional area of the thin copper wire is, for example, at least 0.5 mm², so that during operation of the high-frequency antenna detuning unit 33, heating of the thin copper wire is suppressed, and damage to the thin copper wire is therefore prevented. During operation of the high-frequency antenna detuning unit 33, a direct current of at least several 100 mA flows through the conductor elements 34.

The copper wire is enclosed by the composite material within the antenna segment 35 (FIG. 3). Within a detuning power circuit 36 of the high-frequency antenna detuning unit 33, the copper wire is connected at a first end in a conducting manner to a PIN diode 37 and at a second end by way of a coil 41 to a bias voltage source 38. The coil 41 has a high impedance to suppress unwanted injection of high-frequency signals in the detuning power circuit 36. The antenna segment 35 of the high-frequency antenna 22 is integrated in a high-frequency signal circuit 39.

In a passive operating mode and/or when the high-frequency antenna 22 is not operating, a detuning current is applied to the antenna segment by the high-frequency antenna detuning unit 33, so that a current frequency in the passive operating mode and/or when the high-frequency antenna 22 is not operating differs from an operating frequency of the high-frequency antenna 22 in an operating mode (e.g., a transmit operating mode and/or a receive operating mode of the high-frequency antenna 22).

As an alternative to configuring the conductor element 34 of the high-frequency antenna detuning unit 33 as copper wire, the conductor element 34 may also be configured as a thin conductor layer. The thin conductor layer may be formed from a material that has good electrical conductivity similar to the conductivity of copper. The thin conductor layer, for example, may be formed by a powdered metal, metal flakes, a silver material, a material containing graphite, an indium tin oxide, a fluorine-doped tin oxide, a doped zinc oxide, organic conductor layers made of carbon nanotubes, a graphene material, other materials, or combinations thereof. The cross-sectional area of the thin conductor layer may, for example, be at least 0.5 mm², so that during operation of the high-frequency antenna detuning unit 33, heating of the thin conductor layer and therefore damage to the thin conductor layer are prevented.

FIG. 4 shows a method to produce the high-frequency antenna unit 21 with the shield unit 24, as described above. In this method, a spray process 101 using a spray apparatus (not shown in detail) is used to spray the composite material onto the carrier units 29, 32 to produce the shield unit 24 and the high-frequency antenna 22. The composite material is sprayed onto the radially 20 inner face of the cylindrical carrier unit 29 of the gradient coil 17 during the spray process 101. The composite material is also sprayed onto a radially 20 outer face of the cylindrical carrier unit 32 of the high-frequency antenna 22 during the spray process 101.

Before the spraying process 101, the composite material is transformed to a liquid aggregate state and/or dissolved in a solvent and sprayed in the form of a spray liquid onto the carrier units 29, 32 using the spray apparatus during the spray process. The spray liquid may be, for example, a dye-type liquid containing the liquid and/or dissolved composite material, which is sprayed using a sprayed dye jet onto the carrier units 29, 32. Further embodiments of the spray liquid may be used.

In the liquid aggregate state and/or in the dissolved state, the composite material has a maximum proportion of electrically conducting material of approximately 40% volume (e.g., 30% vol. to 40% volume). The electrically conducting material may include carbon nanotubes and/or the graphene material. By spraying the composite material on in a liquid aggregate state and/or in a state where the composite material is dissolved in a solvent, a regular layer thickness is achieved for the composite material within the high-frequency antenna 22 and the shield unit 24.

To integrate the high-frequency antenna detuning unit 33 in the high-frequency antenna 22, during a positioning process 100, the conductor elements 34 of the high-frequency antenna detuning unit 33 are prepositioned on the cylindrical carrier unit 32, and the composite material is sprayed on in the liquid aggregate state and/or in the dissolved state. After the spraying process 101, a sprayed layer of the composite material dries in a drying process 102. The layer thickness of the composite material on the cylindrical carrier units 29, 32 is, for example, at least 2 μm (e.g., up to several 100 μmm), both for high-frequency antenna 22 and for the shield unit 24. The thicker the layer thickness of the composite material, the more robust and stable the configuration of the shield unit 24 and the high-frequency antenna 22, so the layer thickness may be up to several millimeters.

As an alternative to spraying the composite material onto the carrier elements of the carrier units, the shield unit 24 and the high-frequency antenna 22 may be produced using an injection molding procedure.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A high-frequency antenna unit comprising:
a high-frequency antenna; and
a shield unit,
wherein the shield unit, the high-frequency antenna, or the shield unit and the high-frequency antenna are formed at least partially from a composite material, the composite material comprising at least one electrically conducting material and at least one electrically non-conducting material.

2. The high-frequency antenna unit as claimed in claim 1, wherein an electrically conducting material of the at least one electrically conducting material has an electrical conductivity with a value of at least 30·10⁶ Ω⁻¹m⁻¹.

3. The high-frequency antenna unit as claimed in claim 1, wherein an electrically conducting material of the at least one electrically conducting material comprises electrically conducting material elements that are disposed at least partially isolated from one another within the composite material.

4. The high-frequency antenna unit as claimed in claim 1, wherein an electrically conducting material of the at least one electrically conducting material comprises electrically conducting material elements that are formed at least partially by fibers, threads, or a combination thereof.

5. The high-frequency antenna unit as claimed in claim 1, wherein an electrically conducting material of the at least one electrically conducting material comprises electrically conducting material elements that are formed at least partially by carbon nanotubes.

6. The high-frequency antenna unit as claimed in claim 1, wherein an electrically conducting material of the at least one electrically conducting material comprises electrically conducting material elements that are formed at least partially by a graphene material.

7. The high-frequency antenna unit as claimed in claim 1, wherein the high-frequency antenna comprises a high-frequency antenna detuning unit with at least one conductor element, the at least one conductor element being disposed within an antenna segment.

8. The high-frequency antenna unit as claimed in claim 7, wherein the at least one conductor element comprises a copper wire.

9. The high-frequency antenna unit as claimed in claim 7, wherein a conductor element of the at least one conductor element is disposed at least partially in the form of a thin conductor layer within the antenna segment.

10. The high-frequency antenna unit as claimed in claim 9, wherein the thin conductor layer is formed at least partially by a powdered metal, metal flakes, a silver material, a material containing graphite, an indium tin oxide, a fluorine-doped ton oxide, a doped zinc oxide, an organic conductor layer made of carbon nanotubes, a graphene material, or a combination thereof.

11. The high-frequency antenna unit as claimed in claim 2, wherein an electrically conducting material of the at least one electrically conducting material comprises electrically conducting material elements that are disposed at least partially isolated from one another within the composite material.

12. The high-frequency antenna unit as claimed in claim 2, wherein an electrically conducting material of the at least one electrically conducting material comprises electrically conducting material elements that are formed at least partially by fibers, threads, or a combination thereof.

13. The high-frequency antenna unit as claimed in claim 2, wherein an electrically conducting material of the at least one electrically conducting material comprises electrically conducting material elements that are formed at least partially by carbon nanotubes.

14. A magnetic resonance apparatus comprising:
a magnet unit comprising:
a high-frequency antenna unit comprising:
a high-frequency antenna; and
a shield unit;
a main magnet; and
a gradient unit; and
an evaluation unit,
wherein the shield unit, the high-frequency antenna, or a combination thereof is formed at least partially from a composite material, the composite material comprising at least one electrically conducting material and at least one electrically non-conducting material.

15. A method for producing a high-frequency antenna unit, the method comprising:
producing a shield unit, a high-frequency antenna, or a combination thereof from a composite material, the composite material comprising at least one electrically conducting material and at least one electrically non-conducting material,
wherein the composite material is sprayed onto a carrier unit.

16. The method as claimed in claim 15, wherein the composite material is sprayed onto the carrier unit in a liquid aggregate state, dissolved in a solvent, or a combination thereof.

17. The method as claimed in claim 15, wherein the composite material is sprayed on with a maximum proportion of electrically conducting material of 40% volume.

18. The method as claimed in claim 15, wherein the composite material is sprayed on with an electrically conducting material comprising a graphene material, carbon nanotubes, or a combination thereof.

19. The method as claimed in claim 15, wherein at least one conductor element of a high-frequency antenna detuning unit is positioned on the carrier unit, and the composite material is sprayed onto the carrier unit.

20. A method for producing a high-frequency antenna unit, the method comprising:
producing a shield unit, a high-frequency antenna, or a combination thereof from a composite material, the composite material comprising at least one electrically conducting material and at least one electrically non-conducting material,
wherein the shield unit, the high-frequency antenna, or a combination thereof is produced from the composite material using an injection molding procedure.
